(19) United States
(12) Patent Application Publication
(10) Pub. No.: US 2004/0256733 A1
(43) Pub. Date: Dec. 23, 2004

(54) Method for manufacturing a semiconductor device and a semiconductor device

(76) Inventors: Tadashi Matsuno, Oita-ken (JP); Takeshi Yosho, Oita-ken (JP); Atsushi Sasaki, Oita-ken (JP)

Correspondence Address: Finnegan, Henderson, Farabow,, Garrett & Dunner, L.L.P., 1300 I Street, N.W., Washington, DC, 20005-3315, US

(21) Appl. No.: 10/840,616

(22) Filed: May 7, 2004

(30) Foreign Application Priority Data
May 7, 2003 (JP) 2003-129285

(51) Int. Cl. H01L 27/01

(52) U.S. Cl. 257/774

(57) ABSTRACT

A method for manufacturing a semiconductor device having slit-embedded type wires is provided. The method includes steps of forming a first insulating layer 12 on a semiconductor substrate 11, forming the contact plug 15 in a predetermined area of the first insulating layer 12, and forming the protective insulating layer 20 on the first insulating layer 12 including the contact plug 15. The method further includes steps of forming a second insulating layer 16 on the protective insulating layer 20, forming the opening 17 reaching the protective insulating layer 20 in a predetermined area of the second insulating layer 16 to form the wiring slit 17′, and embedding the metallic wire 18 in the wiring slit 17′ and connecting to the contact plug 15.

### CROSS-REFERENCE TO RELATED APPLICATIONS

This application is based upon and claims the benefit of priority from the prior Japanese Patent Application No. 2003-129285 filed on May 7, 2003; the entire contents of which are incorporated herein by reference.

### BACKGROUND OF THE INVENTION

The present invention relates a method for a semiconductor device having a slit-embedded type metallic wiring structure and to a semiconductor device manufactured by the method.

Generally, a contact plug made of tungsten, for example, (hereinafter referred to as a W-plug) is used for vertical connection between an active element and a wire, which are formed in a semiconductor device. In recent years, copper wires having a low specific resistance have been used in place of conventional Al wires to cope with refinement of a semiconductor device and an increase in resistance due to a lengthening of the wire. It is difficult for the copper wires, unlike the conventional Al wires, to be removed by etching with the wired portions being left after lamination. Thus, generally, wiring slits are formed in an insulating film, in which Cu is embedded to form wires.

FIG. 1 shows a semiconductor device having conventional slit-embedded type metallic wires. An insulating layer 2 made of SiO₂ is formed on a semiconductor substrate 1. On the semiconductor substrate 1, an active element area having isolation layers (STI: Shallow Trench Isolation) 3a and a gate electrode 3b etc. is formed. A contact plug 5 (hereinafter referred to W-plug) composed of a Ti film 5a, a TiN film 5b, and a W film 5c which are sequentially laminated is formed in the insulating layer 2 so as to reach a predetermined position on the semiconductor substrate 1. An insulating layer 6 composed of a SiOF film 6a and a SiO₂ film 6b sequentially laminated is formed over the W-plug 5. A high-melting point metallic wiring layer 8 (hereinafter referred to as Cu wiring layer) composed of a Ta film 8a, Cu films 8b and 8c, which are sequentially laminated, is formed and is connected to the W-plug 5 in a predetermined area of the insulating layer 6.

Generally, such slit-embedded type metallic wires are formed as described below.

Firstly, as shown in FIG. 2a, the insulating layer 2 made of SiO₂ is formed by the CVD (chemical vapor deposit) method on the semiconductor substrate 1 on which the active element area having the isolation layers 3a and a gate electrode 3b etc. is formed. An opening 4 is formed so as to reach the semiconductor substrate 1 at a predetermined position of the insulating layer 2.

Then, as shown in FIG. 2b, the Ti film 5a and the TiN film 5b are sequentially deposited inside the opening as barrier metal films and then the W film 5c is formed to fill the opening 4. The metallic film on the surface of the insulating layer 2 is removed by a chemical mechanical polishing (CMP) method, so as to leave the filler materials only in the opening 4. The W-plug 5 composed of the Ti film 5a, the TiN film 5b, and the W film 5c is thus formed in the insulating film 2 made of SiO₂.

Then, as shown in FIG. 2c, the SiOF film 6a and the SiO₂ film 6b, for example, are sequentially formed as an insulating layer. Then a wiring slit 7 is formed in a predetermined position so as to reach the W-plug 5 by the reactive ion etching (RIE) method.

Thereafter, as shown in FIG. 1, the TaN film 8a and the Cu film b, which are barrier metal films, are sequentially deposited inside the wiring slit 7. With the Cu film 8c embedded and the metallic film on the surface of insulating layer removed, the Cu wiring layer 8 is thus formed to provide the semiconductor device shown in the drawing.

As mentioned above, the wiring slit 7 is formed in the insulating layer 6 by etching to form the Cu wiring layer 8. However, the etching rate applied is actually varied depending on a width or arrangement of the slots for burying the wires. For example, the etching rate in a slit of a wide opening is higher than that in a slit of a narrow opening. When the surface of the W-plug is exposed in the slit of the narrow opening, the insulating layer 2 is so deeply etched that the W-plug 5 is exposed in a convex shape in the slit of the wide wire, as shown in FIG. 3a. Namely, a problem arises that the depth of the wiring slit 7 is varied depending on the width of the wires and on such arrangement as a density of the wires. Thus the difference d′ between the levels of the top surface of the W-plug 5 exposed in a convex shape and the bottom surface of the wiring slit 7 is greatly varied in such a range as 30 to 120 nm.

Furthermore, as shown in FIG. 3b, when the TaN film 8a and the Cu film 8b are deposited by the sputtering method over the W-plug 5, which is exposed in a convex shape, the films deposited become thin at the portion between the wall surfaces of the wiring slit 7 and the W-plug 5 having a narrow distance. Thus, forming of the Cu film 8c in the portion by plating is prevented to form a void 9 due to defective filling. Existence of the void 9 greatly affects the reliability of the device due to variation of the resistance, for example. Particularly, the problem becomes more serious when the width of the W-plug is equal to the wiring width, as shown in FIG. 4a and FIG. 4b, or when refinement of a semiconductor device advances and the width of the wire becomes narrower.

Therefore, it is one of the objects of the present invention to provide a highly reliable semiconductor device and a method for manufacturing therefore, in which the conventional defects are removed by preventing the voids from being occurred in the slit-embedded type wires.

### SUMMARY OF THE INVENTION

A method for manufacturing a semiconductor device according to the present invention includes a step of forming a first insulating layer on a semiconductor substrate, forming a contact plug in a predetermined area of the first insulating layer, forming a protective insulating layer on the first insulating layer and the contact plug, forming a second insulating layer on the protective insulating layer, forming an opening reaching the protective insulating layer in a predetermined area of the second insulating layer, removing the protective insulating layer at the bottom of the opening thereby forming wiring slits, and embedding metallic wires in the wiring slits thereby connecting to the contact plug.

A semiconductor device according to the present invention has a contact plug composed of a high-melting point metal, which is formed in a predetermined area of a first insulating layer formed on a semiconductor substrate, protective insulating layers sequentially laminated on the first insulating layer, and a slit-embedded type metallic wiring layer, which is formed in a predetermined area of a second insulating layer and is connected to the contact plug.

### BRIEF DESCRIPTION OF THE DRAWINGS

FIG. 1 is a cross sectional view showing a semiconductor device manufactured by the conventional semiconductor device manufacturing method,

FIG. 2a, FIG. 2b and FIG. 2c are also cross sectional views showing a semiconductor device manufactured by the conventional method for manufacturing a semiconductor device,

FIG. 3a and FIG. 3b are cross sectional views for showing steps of the conventional method for manufacturing a semiconductor device,

FIG. 4a and FIG. 4b are also cross sectional views for showing steps of the conventional method for manufacturing a semiconductor device,

FIG. 5 is a cross sectional view showing a semiconductor device manufactured by a method for manufacturing a semiconductor device according to the first embodiment of the present invention,

FIG. 6a and FIG. 6b are cross sectional views for showing steps of a method for manufacturing a semiconductor device according to the first embodiment of the present invention,

FIG. 7a and FIG. 7b are also cross sectional views for showing steps of a method for manufacturing a semiconductor device according to the first embodiment of the present invention,

FIG. 8a and FIG. 8b are also cross sectional views for showing steps of a method for manufacturing a semiconductor device according to the first embodiment of the present invention,

FIG. 9 is a cross sectional view for showing a step of a method for manufacturing a semiconductor device according to the first embodiment of the present invention, and

FIG. 10 is a cross sectional view showing a semiconductor device manufactured by the method for manufacturing a semiconductor device according to the second embodiment of the present invention.

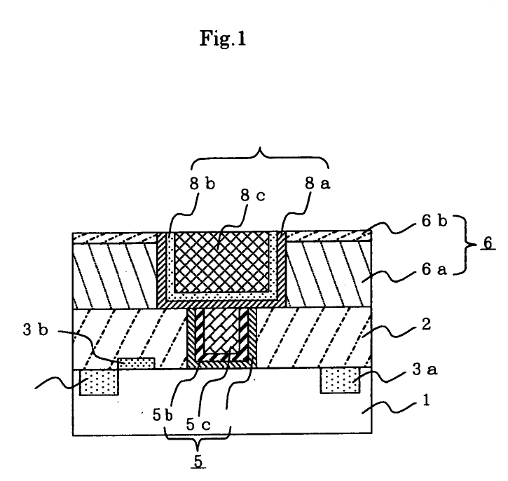

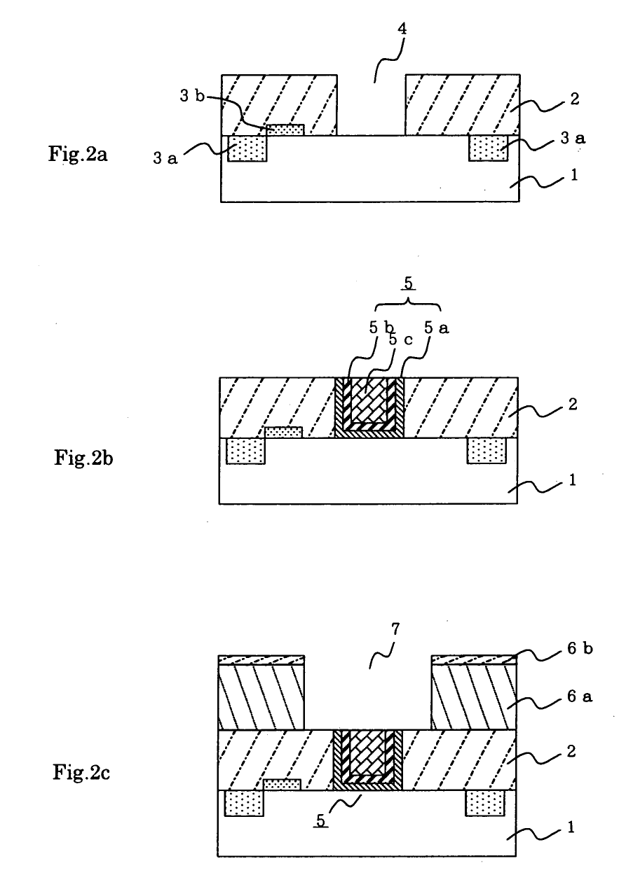

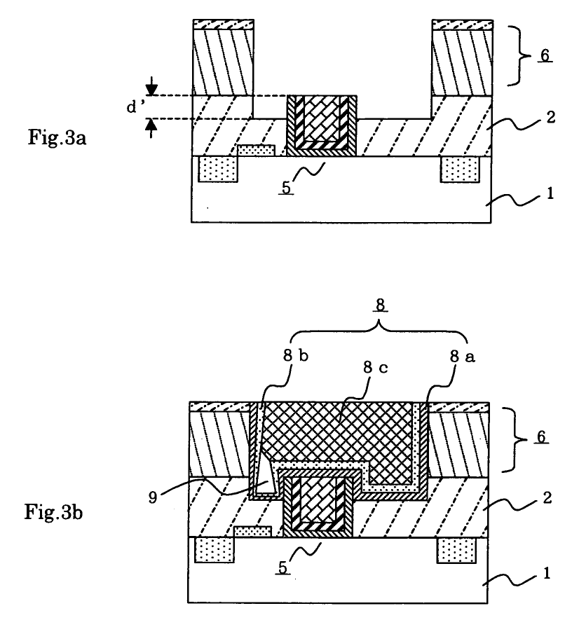

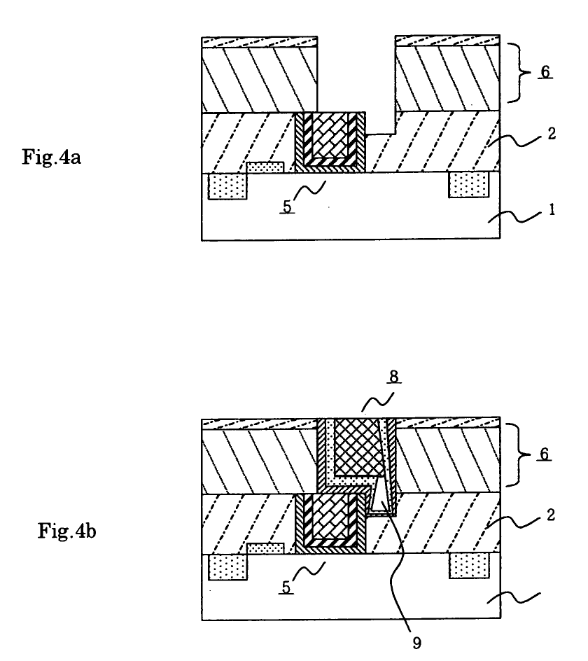

### DETAILED DESCRIPTION OF THE INVENTION

The embodiments of the present invention will be explained hereunder with reference to the accompanying drawings.

(First Embodiment)

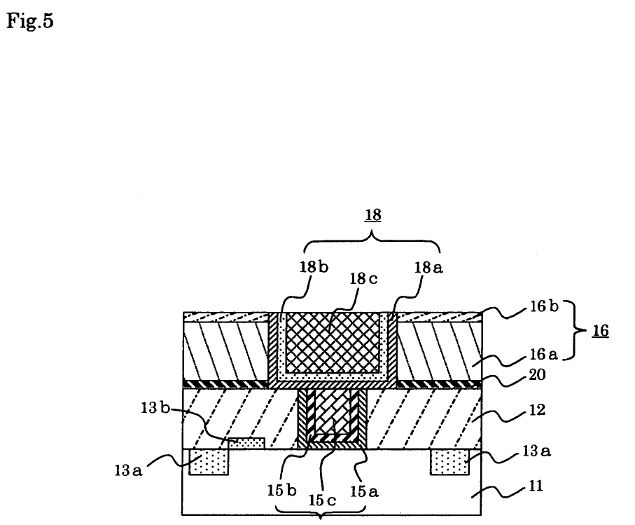

FIG. 5 shows a semiconductor device according to is the first embodiment of the present invention. On a semiconductor substrate 11, a first insulating layer 12 composed of SiO₂ is formed. On the semiconductor substrate 11, an insulating layer 12 composed of SiO₂ is formed. An active element area having shallow trench isolation layers (STI) 13a and a gate electrode 13b etc. is formed on the semiconductor substrate 1. A contact plug 15 (hereinafter referred to W-plug) composed of a Ti film 15a, a TiN film 15b, and a W film 15c, which are sequentially laminated is formed in the insulating layer 12 so as to reach the predetermined area on the semiconductor substrate 11. A protective insulating layer 20 composed of a SiN film and a second insulating layer 16 composed of a SiOF film 16a and a SiO₂ film 16b, which are sequentially laminated is formed on the insulating layer 12. A high-melting point metallic wiring layer 18 (hereinafter referred to as Cu wiring layer) is formed, which is composed of a Ta film 18a, a Cu film 18b, and a plated Cu film 18c, which are sequentially laminated and is electrically connected to the W-plug 15 in its predetermined position.

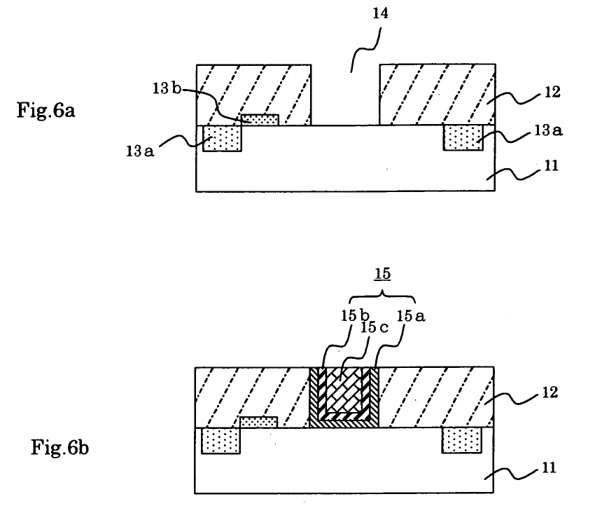

The semiconductor device is manufactured as described below. Firstly, as shown in FIG. 6a, a first insulating layer 12 made of SiO2 film is deposited in a thickness of 1.0 μm by the CVD method on the semiconductor substrate 11, on which the shallow trench isolation layers (STI) 13a and the gate electrode 13b are formed. At this time, the surface layer of 0.2 μm thick of the first insulating layer 12 is removed by the CMP method to flatten the surface where steps are formed by the gate electrode 13b for example. An opening 14 reaching the active element area at a predetermined position of the first insulating layer (SiO₂ film) 12 is formed by the general lithographic technology and the RIE method.

Then, as shown in FIG. 6b, the Ti film 15a is deposited at a thickness of 50 nm on the overall surface including the inside of the opening 14 by the sputtering method. Further, the TiN film 15b is deposited at a thickness of 50 nm by the CVD method. A barrier metal layer composed of the Ti film 15a and the TiN film 15b is thus formed. Then the W film 15c is deposited at a thickness of 240 nm by the CVD method to fill up the opening 14. The metallic films formed at a portion except the opening 14 are removed by the CMP method. The W-plug 15 is thus formed in the opening of the first insulating layer (SiO₂ film) 12. Here, the heights at the surface of the W-plug 15 and at the surface of the first insulating layer (SiO₂ film) 12 are substantially equal to each other, where the difference between them is, for example, less than 10 nm.

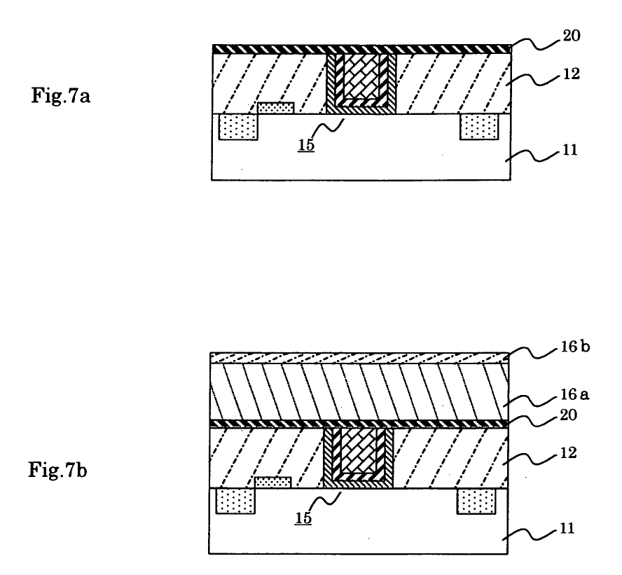

Then, as shown in FIG. 7a, the SiN film forming the protective insulating layer 20 is deposited at a thickness of 50 nm by the CVD method. Then, as shown in FIG. 7b, the SiOF film 16a and the SiO₂ film 16b, which form an insulating layer 16, are continuously deposited at thicknesses of 250 nm and 50 nm respectively by the CVD method.

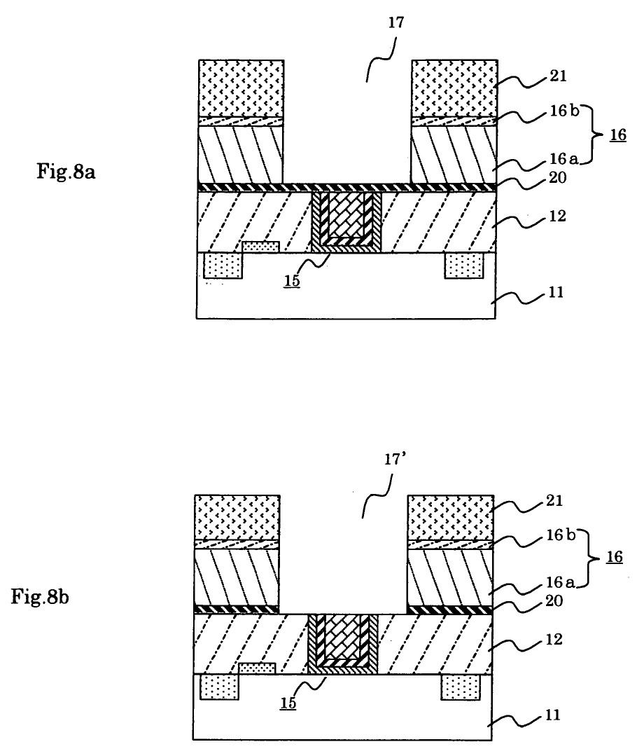

Then, as shown in FIG. 8a, a resist layer 21 is coated and is patterned by the general lithographic technology. An opening 17 is formed in a predetermined area of the insulating layer 16 composed of the SiOF film 16a and the Si film 16b using a magnetron RIE device, for example, with a selective etching ratio of the SiOF film 16a to the protective insulating layer (SiN film) 20 set to be more than 10. Here, the RIE is carried out using, for example, C₄H₈, CO, Ar, or O₂ as a mainly gas with the partial pressure of C₄H₈ at 150 m Torr. Since the selective ratio of the etching is sufficiently large, the protective insulating layer (SiN film) 20 functions as a stopper. Namely, when reaching the protective insulating layer (SiN film) 20, the progress of etching is so controlled by itself to stop at the protective insulating layer (SiN film) 20 at any portion of the opening. The height of the bottom of the opening 17 is thus made almost equal irrespective of the width or arrangement of the W-plug 15.

Once stopping the etching at the protective insulating layer (SiN film) 20, the RIE is carried out with the etching gas switched to a gas composed mainly of CF₄/Ar/N₂ or of CHF₃/CO/O₂/Ar, and with a partial pressure of CHF₃ chosen at 150 m Torr. As shown in FIG. 8b, the protective insulating layer (SiN film) 20 is uniformly etched until the surface of the W-plug 15 is exposed. After a wiring slit 17′ is thus formed, the resist layer 21 is removed by RIE. At this time, the heights of the W-plug 15 and the first insulating layer 12 (SiO₂ film) are almost equal to each other, with a difference between them of, for example, less than 40 nm.

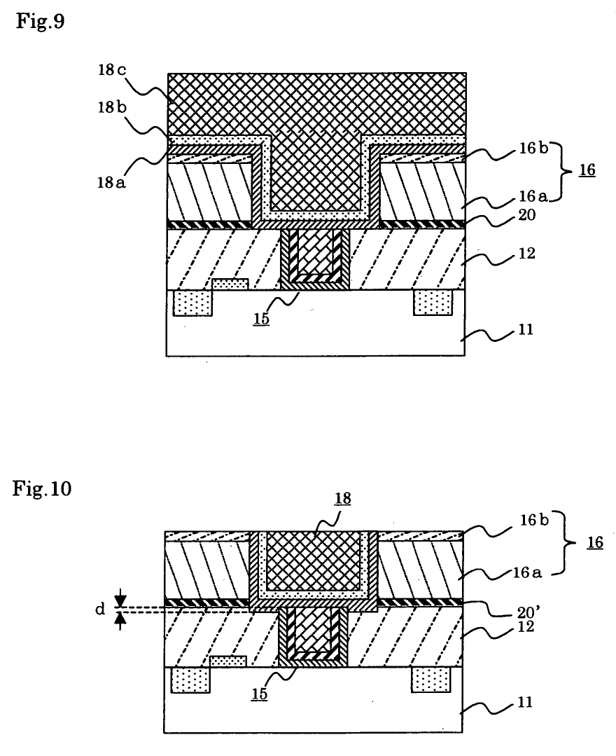

The TaN film 18a and the Cu film 18b are sequentially deposited as barrier metals by the conventional sputtering method at a thickness of 10 nm and of 50 nm respectively on the surface of the insulating layer 16 including the inside of the wiring slit 17′, as shown in FIG. 9A. Then the Cu film 18c is formed at a thickness of 700 nm by the plating method, thereby filling the wiring slit. Since the W-plug 15 is not so largely exposed in a convex shape as in the conventional method for manufacturing, the TaN film 18a and Cu film 18b are formed by sputtering with high quality, and the Cu film 18c is formed by the plating without forming voids. The metallic film on the surface of the insulating layer 16 is removed by the CMP method so as to leave the filling material only in the wiring slit. In this way, the Cu wiring layer 18 composed of the TaN film 18a and the Cu films 18b and 18c is formed in the insulating layer composed of the SiN film 20, the SiOF film 16a, and the SiO₂ film 16b as shown in FIG. 5.

(Second Embodiment)

FIG. 10 shows a semiconductor device manufactured according to the second embodiment of the present invention. In the drawing, the same numerals are assigned to the parts corresponding to those of the semiconductor device according to the first embodiment, thereby omitting a detailed explanation.

In the embodiment, the W-plug 15 is formed in the opening of the first insulating layer (SiO₂ film) 12, in the same way as with the first embodiment. Then a SiOC film (SiC film) is formed at a thickness of 30 nm in place of the SiN film as a protective insulating layer 20′. Here, since the SiOC film is easier to realize a necessary selective ratio of etching than the SiN film, the SiOC film functions as a protective insulating layer with a thinner film. The SiOF film 16a and the SiO₂ film 16b are deposited continuously in the same way as described with the first embodiment.

Then, an opening is formed in a predetermined position at the SiOF film 16a and the SiO₂ film 16b, using the general lithographic technology and RIE method in the same way. Stopping the etching once, SiOC film as the protective insulating layer 20′ is uniformly etched until the surface of the W-plug 15 is exposed, and the wiring slit 17′ is formed. Here, a slight level difference d between the surface of the first insulating layer (SiO₂ film) 12 and the bottom surface of the wiring slit 17′ may be allowed by dishing at the flattening step or over etching for perfectly removing the protective insulating layer 20′ on the W-plug 15. For example, in a case of a wire width of about 180 nm, d may be about 50 nm or less (d≦50 nm). The level difference d is substantially constant irrespective of variations of due to the wire width and of arrangement of the W-plug 15 as it is true in the first embodiment.

The wiring slit 17′is filled with the TaN film 18a, the Cu film 18c and the plated Cu film 18c, and the metallic film on the surface is removed by the CMP method. Thus the Cu wiring layer 18, composed of the TaN film 18a, the Cu films 18b and 18c is formed with good quality in the same way as with the first embodiment.

Although the embodiments according to the present invention are explained in detail above, the present invention is not limited to the above embodiments and can be modified variously. For example, the materials used for the respective layers are not limited to those used in these embodiments. For the contact plug, Cu may be used instead of W with a small amount of F, Si, or H contained. For the metallic wiring layer 18, a small amount of O, Cl, Si, S, or C may be contained in addition to Cu. Further, the barrier metal may contain Ni or Nb in addition to Ti or Ta.

With respect to the protective insulating layers 20 and 20′, a higher dielectric constant is required than that of the second insulating layer 16 formed right above them, so as to make the selective ratio in etching of the protective insulating layers 20 and 20′ to the second insulating layer 16 to 5 or more, preferably 10 or more. Thus, a SiN film and a SiC film (SiOC film) having a high specific dielectric constant are used for the protective insulating layer 20 and 20′, with the thickness preferably within the range from 5 to 100 nm. When the thickness is less than 5 nm, stable film cannot be forming. While, when the thickness is more than 100 nm, the dielectric constant between the wires is increased. Further, the second insulating layer 16 formed right above the protective insulating layers 20 and 20′ may have a lower specific dielectric constant than that of the protective insulating layers 20 and 20′. For example, not only a SiOF film having a specific dielectric constant of less than 3.7 but also SiO₂ whose specific dielectric constant is controlled to less than 4.2 can be used. On such insulating films, a SiO2 film or other insulating films generally used may be laminated in the same way as with this embodiment. The protective insulating layer not only composed of two layers but also of a single layer or multi-layers may be used.

Although each insulating film is formed by the CVD method, it may be formed by a coating method and thereafter it may be subject to surface or heat treatment using a chemical solution, the RIE method or CMP method.

According to the present invention, a method is provided for manufacturing a highly reliable semiconductor device having slit-embedded type wires with no voids therein.

What is claimed is:

1. A method for manufacturing a semiconductor device comprising steps of:
forming a first insulating layer on a semiconductor substrate,
forming a contact plug in a predetermined area of the first insulating layer,
forming a protective insulating layer on the first insulating layer and the contact plug,
forming a second insulating layer on the protective insulating layer,
forming an opening reaching the protective insulating layer in a predetermined area of the second insulating layer,
removing the protective insulating layer at the bottom of the opening thereby forming wiring slits, and
embedding metallic wires in the wiring slits thereby connecting to the contact plug.

2. A method for manufacturing a semiconductor device according to claim 1, wherein the step of forming the opening further comprises steps of selectively etching a predetermined area of the second insulating layer and stopping the etching at the protective insulating layer.

3. A method for manufacturing a semiconductor device according to claim 2, wherein the second insulating layer has a larger selective ratio of etching than the protective insulating layer.

4. A method for manufacturing a semiconductor device according to claim 2, wherein the step of forming wiring slits further comprises a step of removing by etching the protective insulating layer under different conditions from that of the second insulating layer.

5. A method for manufacturing a semiconductor device according to claim 3, wherein a specific dielectric constant of said second insulating layer is lower than that of the protective insulating layer.

6. A method for manufacturing a semiconductor device according to claim 5, wherein the protective insulating layer has a film composed of any one of SiN, SiC, and SiOC.

7. A method for manufacturing a semiconductor device according to claim 5, wherein the second insulating layer is a film having a specific dielectric constant of less than 4.2.

8. A method for manufacturing a semiconductor device according to claim 5, wherein the second insulating layer is a film having a specific dielectric constant of less than 3.7.

9. A method for manufacturing a semiconductor device according to claim 5, wherein the second insulating layer has a film composed of either of SiOF and SiO₂.

10. A method for manufacturing a semiconductor device according to claim 9, wherein said protective insulating layer is formed with a thickness within the range from 5 nm to 100 nm.

11. A semiconductor device comprising:
a first insulating layer formed on a semiconductor substrate,
a contact plug composed of a high-melting point metal, which is formed at a predetermined area of a first insulating layer formed on a semiconductor substrate,
a protective insulating layer laminated on the first insulating layer,
a second insulating layer laminated on said protective insulating layer, and
a slit-embedded type metallic wiring layer, which is formed at a predetermined area of the second insulating layer and is connected to the contact plug.

12. A semiconductor device according to claim 11, wherein the levels of the surfaces of the contact plug and of the first insulating layer are substantially equal.

13. A semiconductor device according to claim 11, wherein a difference between the levels of the surfaces of the contact plug and of the first insulating layer is 50 nm or less.

14. A semiconductor device according to claim 10, wherein a specific dielectric constant of the protective insulating layer is higher than that of the second insulating layer.

15. A semiconductor device according to claim 14, wherein the protective insulating layer has a film composed of any one of SiN, SiC, and SiOC.

16. A semiconductor device according to claim 14, wherein the second insulating layer is a film having a specific dielectric constant of less than 4.2.

17. A semiconductor device according to claim 14, wherein the second insulating layer is a film having a specific dielectric constant of less than 3.7.

18. A semiconductor device according to claim 14, wherein the second insulating layer has a film composed of either one of SiOF and SiO₂.

19. A semiconductor device according to claim 11, wherein the protective insulating layer is formed at a thickness within the range from 5 nm to 100 nm.

20. A semiconductor device according to claim 11, wherein the metallic wiring layer has a high-melting point metallic layer containing Cu as a main component.

21. A semiconductor device according to claim 11, wherein the contact plug has a high-melting point metallic layer containing W as a main component.
